(19) United States
(12) Patent Application Publication
(10) Pub. No.: US 2013/0214342 A1
(43) Pub. Date: Aug. 22, 2013

(54) NONVOLATILE SEMICONDUCTOR STORAGE DEVICE AND METHOD OF MANUFACTURE THEREOF

(71) Applicant: Hiroyasu Sato, Kanagawa-ken (JP)

(72) Inventor: Hiroyasu Sato, Kanagawa-ken (JP)

(73) Assignee: KABUSHIKI KAISHA TOSHIBA, Tokyo (JP)

(21) Appl. No.: 13/605,931

(22) Filed: Sep. 6, 2012

(30) Foreign Application Priority Data
Feb. 22, 2012 (JP) P2012-036374

(51) Int. Cl. H01L 29/788

(52) U.S. Cl. CPC H01L 29/788
USPC 257/316; 438/260

(57) ABSTRACT

A nonvolatile semiconductor storage device includes a semiconductor substrate including a protruding active area, a gate insulating layer on the active area, floating gate electrodes on the gate insulating layer, an insulating layer on the floating gate electrodes extending in a row direction, and a control gate electrode on the insulating layer extending in the row direction. The floating gate electrodes include a semiconductor layer on the gate insulating layer and a metal layer on the semiconductor layer. The width of the semiconductor layer of the floating gate electrodes in the row direction is narrower than the width of the metal layer in the row direction.

### CROSS-REFERENCE TO RELATED APPLICATION

This application is based upon and claims the benefit of priority from Japanese Patent Application No. 2012-036374, filed Feb. 22, 12; the entire contents of which are incorporated herein by reference.

### FIELD

Embodiments described herein relate to a nonvolatile semiconductor storage device and its manufacturing method.

### BACKGROUND

In nonvolatile semiconductor storage devices such as NAND flash memory, a flat cell structure amenable for miniaturization has recently been utilized.

The flat cell structure has an advantage that since an insulating layer between field gate electrodes and a control gate electrode is not introduced among plural floating gates that are arranged in a row direction along which a control gate electrode (word line) extends, a half (half pitch) of the pitch of plural bit lines extending in a column direction is not limited by the insulating layer and the control gate electrode.

However, if the half pitch is narrowed in the flat cell structure, a so-called interference between adjacent cells in which plural memory cells arranged in the row direction interfere with each other occurs during a readout and write operation.

### DESCRIPTION OF THE DRAWINGS

FIG. 1 is a plan view showing an array structure according to a first embodiment.

FIG. 2 is a cross section at the II-II line of FIG. 1.

FIG. 3 is a cross section at the III-III line of FIG. 1.

FIG. 4 is a cross section showing an array structure according to a second embodiment.

FIG. 5 is a cross section showing an array structure according to a third embodiment.

FIG. 6 is a cross section showing an array structure according to the third embodiment.

FIG. 7 is a perspective view showing the manufacturing method.

FIG. 8 is a perspective view showing the manufacturing method.

FIG. 9 is a perspective view showing the manufacturing method.

FIG. 10 is a perspective view showing the manufacturing method.

FIG. 11 is a perspective view showing the manufacturing method.

FIG. 12 is a perspective view showing the manufacturing method.

FIG. 13 is a perspective view showing the manufacturing method.

FIG. 14 is a perspective view showing the manufacturing method.

FIG. 15 is a perspective view showing the manufacturing method.

FIG. 16 is a perspective view showing the manufacturing method.

FIG. 17 is a perspective view showing the manufacturing method.

FIG. 18 is a perspective view showing the manufacturing method.

FIG. 19 is a perspective view showing the manufacturing method.

FIG. 20 is a perspective view showing the manufacturing method.

FIG. 21 is a perspective view showing the manufacturing method.

FIG. 22 is a perspective view showing the manufacturing method.

FIG. 23 is a perspective view showing the manufacturing method.

FIG. 24 is a perspective view showing the manufacturing method.

FIG. 25 is a perspective view showing the manufacturing method.

FIG. 26 is a plan view showing a loop cut process.

FIG. 27 is a perspective view showing the manufacturing method.

FIG. 28 is a perspective view showing the manufacturing method.

### DETAILED DESCRIPTION

Embodiments will be explained with reference to the figures. Embodiments disclosed herein provide a technique for preventing interference between adjacent cells in a flat cell structure.

According to an embodiment, the nonvolatile semiconductor storage device is provided with a semiconductor substrate, a first fin-type active area on the semiconductor substrate, a first gate insulating layer on the first fin-type active area, a first floating gate electrode on the first gate insulating layer, an insulating layer between the first floating gate electrode and a control gate electrode, the insulating layer extending in a first direction on the first floating gate electrode, and the control gate electrode extending in the first direction on the insulating layer between the first floating gate electrode and the control gate electrode. The first floating gate electrode is provided with a first semiconductor layer on the first gate insulating layer and a first metal layer on the first semiconductor layer, and the width in the first direction of the first semiconductor layer is narrower than the width in the first direction of the first metal layer.

Another embodiment of the present disclosure relates to a method for manufacturing a nonvolatile semiconductor storage device, including a process for narrowing the width in the first direction of the first semiconductor layer more than the width is narrowed in the first direction of the first metal layer. The method includes: a process for forming a first oxide layer on the surface in the first direction of the first semiconductor layer by oxidizing the surface in the first direction of the first semiconductor layer at the same time as the oxidation of the surface of the first metal layer; a process for selectively removing the first oxide layer; and a process for forming a second oxide layer on the surface in the first direction of the first semiconductor layer by re-oxidizing the surface in the first direction of the first semiconductor layer.

### Embodiment 1

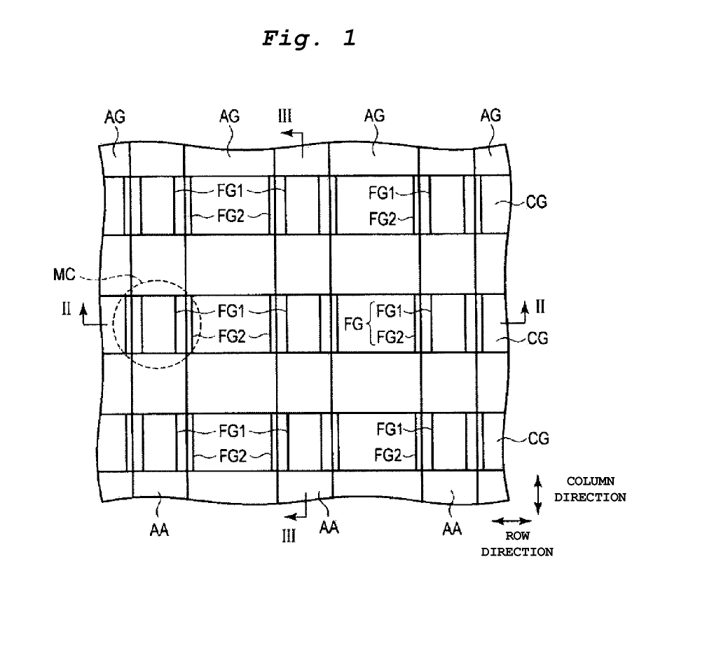

FIG. 1 to FIG. 3 show a structure of a first Embodiment.

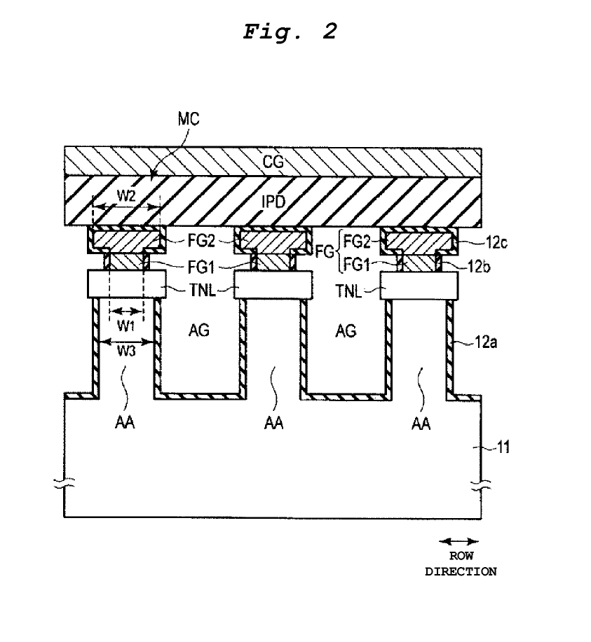

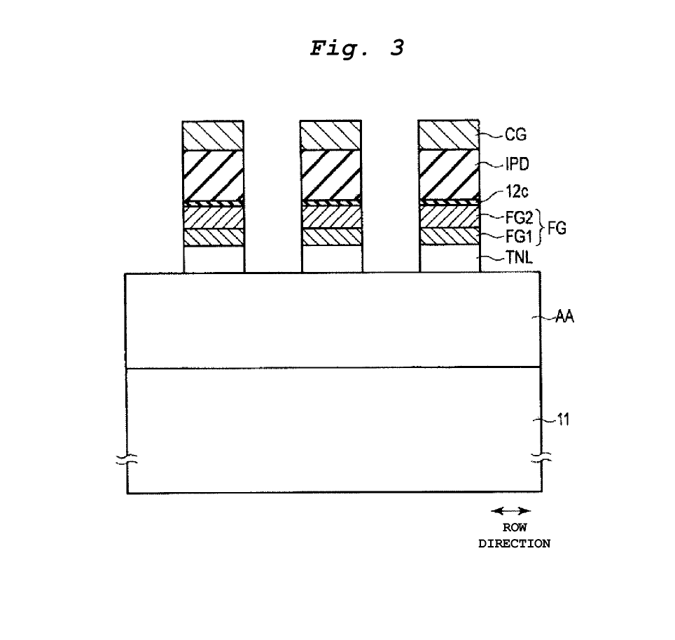

FIG. 1 is a plan view showing a memory cell array, FIG. 2 is a cross section along II-II line of FIG. 1, and FIG. 3 is a cross section along III-III line of FIG. 1.

A semiconductor substrate 11, for example, is a silicon substrate. The upper surface of the semiconductor substrate 11 is concave in certain areas and convex in other areas, and a number of convex parts each constitute a fin-type active area AA. A number of fin-type active areas AA are arranged in a row direction (first direction) and extend in a column direction (second direction) perpendicular to the row direction.

The upper surface (bottom faces of plural concave parts) of the semiconductor substrate 11 and the side surfaces of the fin-type active areas AA are covered with an insulating layer 12a. The insulating layer 12a, for example, is an oxide layer that is formed by oxidizing the semiconductor substrate 11. The insulating layer 12a prevents electrons in the fin-type active areas (channels) AA from escaping into air gaps AG.

In this example, a group of fin-type active areas AA are part of the semiconductor substrate 11; however these active areas are not limited to being a part of the semiconductor substrate. For example, plural fin-type active areas may be semiconductor layers such as epitaxial layers on the semiconductor substrate 11.

In each fin-type active area AA, a group of memory cells of a field effect transistor (FET) type is arranged. The memory cells (MCs) on one fin-type active area AA, for example, are connected in series in a column direction, forming a NAND string. Nine MCs are found in FIG. 1, with each one being located at an intersection of an AA and a CG, although only one MC is labeled in FIG. 1 for the sake of convenience.

Each memory cell MC is provided with a gate insulating film (e.g., tunnel insulating film TNL) on the fin-type active area AA, a floating gate electrode FG on the gate insulating film TNL, and an insulating layer (e.g., inter-poly dielectric (IPD)) between the floating gate electrode and a control gate electrode. The IPD is on the floating gate electrode FG, and the control gate electrode CG is on the insulating layer IPD between the electrodes.

The gate insulating layer TNL, for example, is a silicon oxide layer and is formed by oxidizing the upper surface of the fin-type active area AA.

The floating gate electrode FG comprises a semiconductor layer FG1 on the gate insulating layer TNL and a metal layer FG2 on the semiconductor FG1. The width W1 of the semiconductor layer FG1 in the row direction is narrower than the width W2 of the metal layer FG2 in the row direction. Thus FG1 is located further from neighboring AAs, thereby helping to prevent interference between the adjacent cells.

The semiconductor layer FG1 is covered with an oxide layer 12b which is an oxide of a material from which the semiconductor layer FG1 is composed. The semiconductor layer FG1, for example, is a polysilicon layer, and the oxide layer 12b, for example, is a silicon oxide layer. The oxide layer 12b prevents electrons accumulated in the semiconductor layer FG1 from escaping into the air gap AG.

In addition, the metal layer FG2 is covered with an oxide layer 12c which is an oxide of a material from which the metal layer FG2 is composed. The metal layer FG2, for example, is a titanium (Ti) layer, tungsten (W) layer, tantalum (Ta) layer, etc., and the oxide layer 12c, for example, is a titanium oxide layer, tungsten oxide layer, tantalum oxide layer, etc.

The metal layer FG2 includes a metal silicide layer such as a titanium silicide layer, a tungsten silicide layer, or a tantalum silicide layer. The oxide layer 12c prevents electrons accumulated in the metal layer FG2 from escaping into the air gap AG. In addition, the oxide layer 12c has a trap-assist effect for trapping the electrons in the floating gate electrode FG.

The insulating layer IPD between the electrodes, for example, is formed of a highly dielectric material having a dielectric constant higher than that of the oxide layer 12b to improve the coupling ratio of the memory cells. The material with a high dielectric constant, for example, is a metal oxide such as Al₂O₃, ZrO₂, HfAlO, LaAlO₃ (LAO), and LaAlSiO(LASO) or a laminated structure of either of these metal oxides. In addition, the material with a high dielectric constant may also be a laminated structure of a silicon oxide layer and a silicon nitride layer, such as ONO.

The insulating layer IPD between the electrodes is also called an insulating layer between polysilicon (or inter-polysilicon dielectric: IPD) when the floating gate electrode FG and the control gate electrode CG include a polysilicon layer.

The control gate electrode CG is provided with a polysilicon layer, metal silicide layer, or a laminated structure of either of polysilicon or metal silicide. The control gate electrode CG and the insulating layer IPD between the electrodes extend in the row direction. The control gate electrode CG constitutes a word line.

In this example, the gaps among plural fin-type active areas AA are the air gaps AG. These gaps are effective for enhancing the prevention of interference between the adjacent cells due to the shape of the floating gate FG.

However, part or all of the gaps among plural fin-type active areas AA may be filled with interlayer insulating layers (for example, silicon oxide layers).

Here, in this example, the width W3 in the row direction of each fin-type active area AA is the same as or greater than the width W1 in the row direction of the semiconductor layer FG1 that constitutes the lower part of the floating gate electrode FG. It is also smaller than the width W2 in the row direction of the metal layer FG2 that constitutes the upper part of the floating gate electrode FG. In other words, W1≦W3<W2.

The prevention of the interference between the adjacent cells is improved as the width W3 in the row direction of each fin-type active area AA is narrowed. However, as the width W3 is narrowed, the fin strength of each fin-type active area AA is weakened, causing possibility of a collapse of each fin-type active area AA.

Therefore, the width W3 in the row direction of each fin-type active area AA is set to a value based upon consideration of both the interference between the adjacent cells and the fin strength.

In addition, in this example, plural memory cells MC, which are arranged in the column direction, have no diffusion layer in the fin-type active areas AA. The reason for this is that if each memory cell MC is miniaturized, channels can be formed in the fin-type active areas AA by a so-called fringe effect, even if there is no diffusion layer.

However, each memory cell MC may include a diffusion layer in the fin-type active areas AA.

According to the cell array structure of the first Embodiment, the interference between the adjacent cells can be effectively prevented in the flat cell structure.

### Embodiment 2

FIG. 4 shows a structure of a second Embodiment.

The second embodiment is a modified example of the first Embodiment, and FIG. 4 corresponds to the cross section of FIG. 2.

The difference between the cell array structure of this Embodiment and the cell array structure of the first Embodiment is oxide layers 12b, 12c, and 12d which cover the floating gate electrode FG. Since the other components are the same as those of the first Embodiment, their explanation is omitted here.

The floating gate electrode FG is provided with a semiconductor layer FG1 on a gate insulating layer TNL and a metal layer FG2 on the semiconductor layer FG1. The width W1 in the row direction of the semiconductor layer FG1 is narrower than the width W2 in the row direction of the metal layer FG2.

The semiconductor layer FG1 is covered with an oxide layer 12b which is an oxide of a material used to form the semiconductor layer FG1. The semiconductor layer FG1, for example, is a polysilicon layer, and the oxide layer 12b, for example, is a silicon oxide layer.

In addition, the metal layer FG2 is covered with oxide layers 12c and 12d which are oxides of a material used to form the metal layer FG2. The metal layer FG2, for example, is a titanium, tungsten, or tantalum layer, or a titanium silicide, tungsten silicide or tantalum silicide layer, and each oxide layer 12c and 12d, for example, is a titanium oxide layer, tungsten oxide layer, or tantalum oxide layer.

Here, the oxide layer 12c is aggressively formed by an oxidation treatment in order to add an offset to the width W1 in the row direction of the semiconductor layer FG1 and the width W2 in the row direction of the metal layer FG2. On the contrary, the oxide layer 12d is naturally formed by native oxidation after flattening the underlying FG2, and before forming the insulating layer IPD between the field gate electrodes and the control gate electrode CG.

In other words, the thickness of the oxide layer 12d (film thickness when the oxide layer 12d is assumed as a film) is less than the thickness of the oxide layer 12c (film thickness when the oxide layer 12c is assumed as a film).

The oxide layer 12d may also be an insulating layer such as a nitride layer or an oxynitride layer. In addition, the oxide layer 12d may be omitted.

In the cell array structure of the second Embodiment, the interference between the adjacent cells can also be effectively prevented in the flat cell structure.

### Embodiment 3

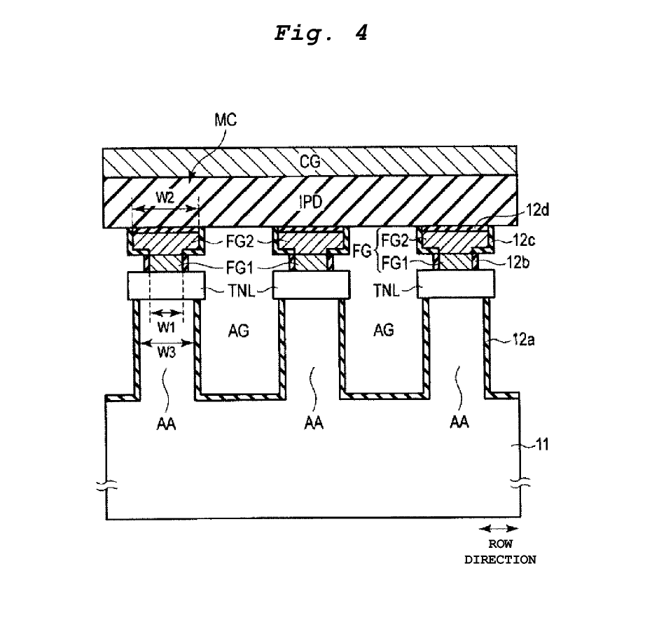

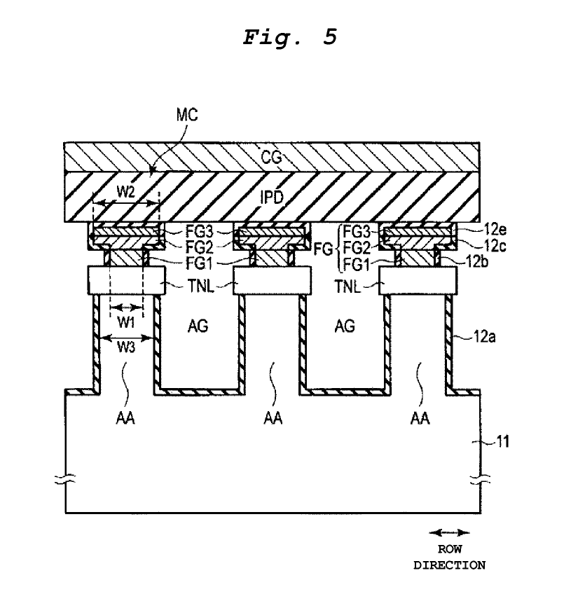

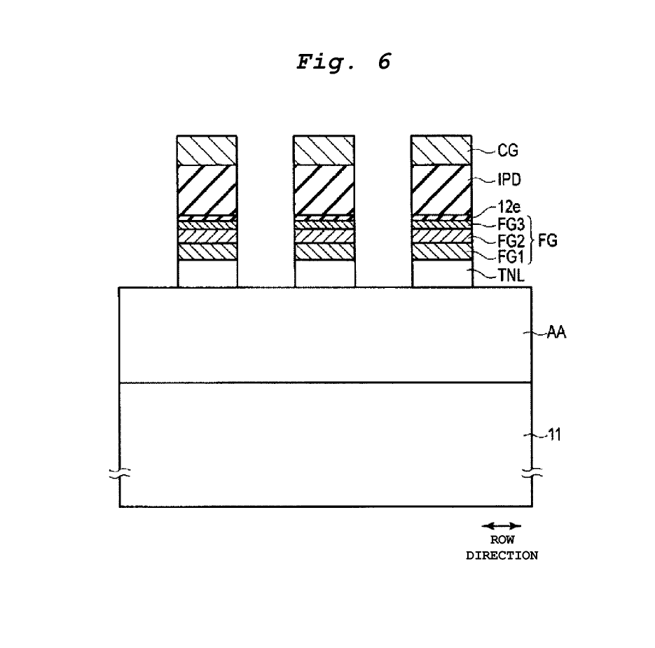

FIG. 5 and FIG. 6 show a structure of a third Embodiment.

This Embodiment is also a modified example of the first Embodiment. FIG. 5 is a view which corresponds to the cross sectional view of FIG. 2, and FIG. 6 is a view which corresponds to the cross sectional view of FIG. 3.

The difference between the cell array structure of this Embodiment and the cell array structure of the first Embodiment is that a floating gate electrode FG is provided with a semiconductor layer FG1 and two metal layers FG2 and FG3. In other words, there is a multiple layer structure in the floating gate FG. Since the other components are the same as those of the first Embodiment, their explanation is omitted here.

The floating gate electrode FG is provided with the semiconductor layer FG1 on a gate insulating layer TNL and the metal layers FG2 on the semiconductor FG1. The metal layer FG3 is disposed on the metal layer FG2. The width W1 in the row direction of the semiconductor layer FG1 is narrower than the width W2 in the row direction of the metal layers FG2 and FG3.

The semiconductor layer FG1 is covered with an oxide layer 12b which is an oxide of a material found in the semiconductor layer FG1. The semiconductor layer FG1, for example, is a polysilicon layer, and the oxide layer 12b, for example, is a silicon oxide layer.

In addition, the metal layers FG2 and FG3 are covered with oxide layers 12c and 12e which are oxides of materials found in the metal layers FG2 and FG3. Each of the metal layers FG2 and FG3, may be, for example, a titanium, tungsten, or tantalum layer, or a titanium oxide, tungsten oxide, or tantalum oxide. Oxide layers 12c and 12e, for example, may be a titanium oxide layer, tungsten oxide layer, or tantalum oxide layer.

Here, the metal layers FG2 and FG3 are formed of materials that are different from each other.

However, metal layer FG includes part or all of the composition from which the metal layer FG3 is formed. For example, the metal layer FG3 may be a titanium layer, tungsten layer, or tantalum layer, etc., while the metal layer FG2 may be a titanium silicide layer, tungsten silicide layer, tantalum silicide layer, etc.

In the cell array structure of the third Embodiment, interference between adjacent cells can also be effectively prevented in the flat cell structure.

### Manufacturing Methods

The methods for manufacturing the cell array structures of the first to third Embodiments will be explained.

The following manufacturing method relates to the structure of the first Embodiment shown in FIGS. 1-3. However, since the structure of the second Embodiment shown in FIG. 4 and the structure of the third Embodiment shown in FIG. 5 and FIG. 6 can also be formed simply by slightly re-arranging the following manufacturing method, they will also be appropriately explained.

First, as shown in FIG. 7, the gate insulating layer TNL, semiconductor layer FG1, and insulating layers 21 and 22 are sequentially formed above the semiconductor substrate 11. The semiconductor layer FG1, for example, may be a polysilicon layer, the insulating layer 21, for example, is a silicon nitride layer, and the insulating layer 22, for example, is a tetraethoxysilane (TEOS) layer.

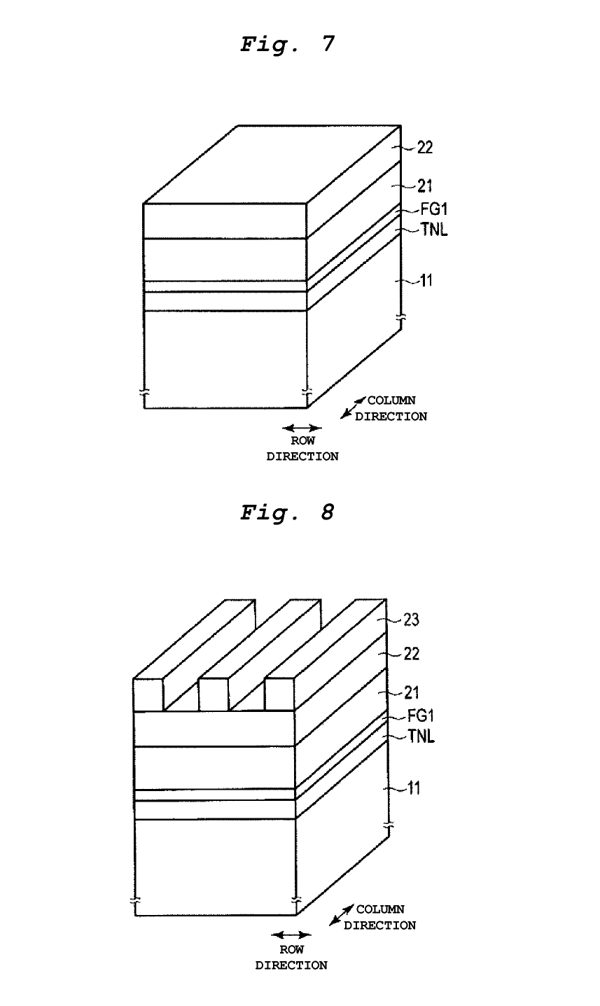

Next, as shown in FIG. 8, a photoresist layer 23 is formed on the insulating layer 22 by PEP (photoengraving process). The photoresist layer 23 has a line-and-space pattern that is arranged at a fixed pitch in the row direction and extends in the column direction. Next, using the photoresist layer 23 as a mask, the insulating layers 21 and 22 are patterned by RIE (reactive ion etching).

Next, the photoresist layer 23 is removed, and the insulating layer 22 is removed by wet-etching with dilute hydrofluoric acid (dilute HF: DHF).

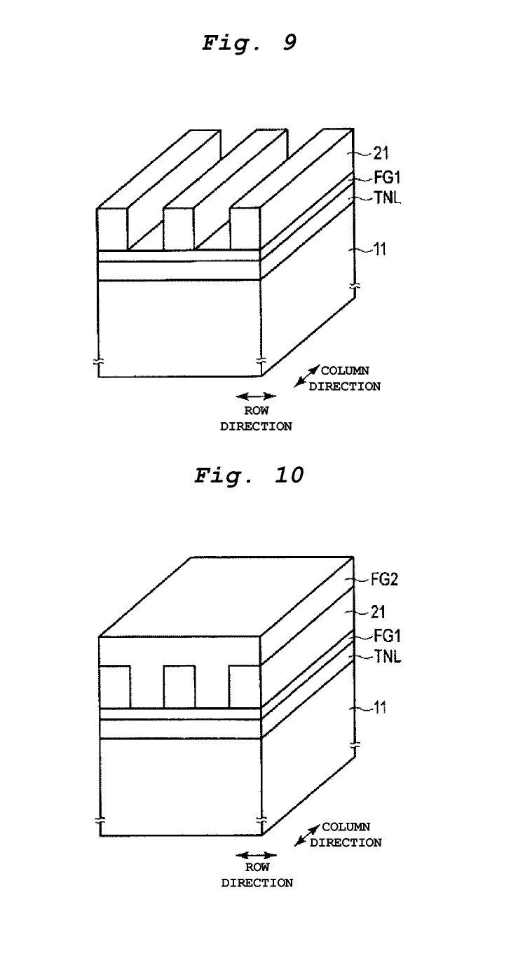

As a result, as shown in FIG. 9, the insulating layer 21, which has a line-and-space pattern arranged at a fixed pitch in the row direction and extends in the column direction, is formed.

Next, as shown in FIG. 10, the metal layer FG2, which completely fills the cavities (concave part) of the insulating layer 21 having a line-and-space pattern, is formed by a sputtering method. The metal layer FG2, for example, is a titanium layer, tungsten layer, or tantalum layer, etc.

Next, the metal layer FG2 is polished by CMP (chemical mechanical polishing) until the upper surface of the insulating layer 21 is exposed.

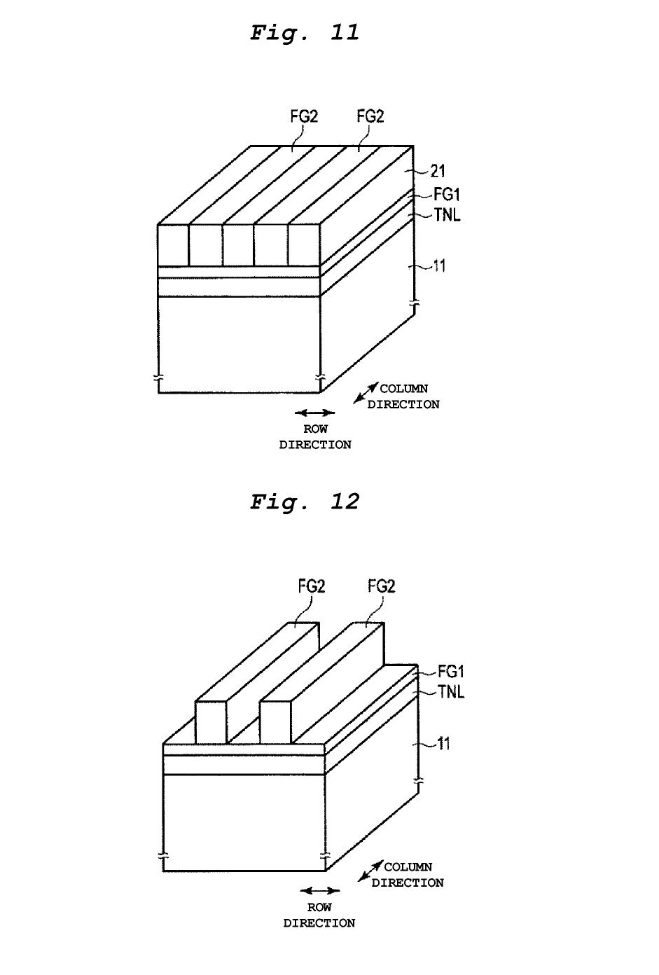

As a result, as shown in FIG. 11, the remaining metal layer FG2 resides only in the cavities (concave part) of the insulating layer 21. Next, if the insulating layer 21 is removed by wet-etching with phosphoric acid, as shown in FIG. 12, the metal layer FG2, having a line-and-space pattern arranged at a fixed pitch in the row direction and extending in the column direction, is formed.

Here, the above process is the manufacturing method of the metal layer FG2 of the first and second Embodiments utilizing a so-called Damascene process. The metal layers FG2 and FG3 of the third Embodiment can also be formed by the same process as this process.

For example, the metal layer (titanium layer, tungsten layer, or tantalum layer, etc., as the case may be) FG2 in the process of FIG. 10 to FIG. 12, may be replaced with the metal layer (titanium layer, tungsten layer, tantalum layer, etc.) FG3.

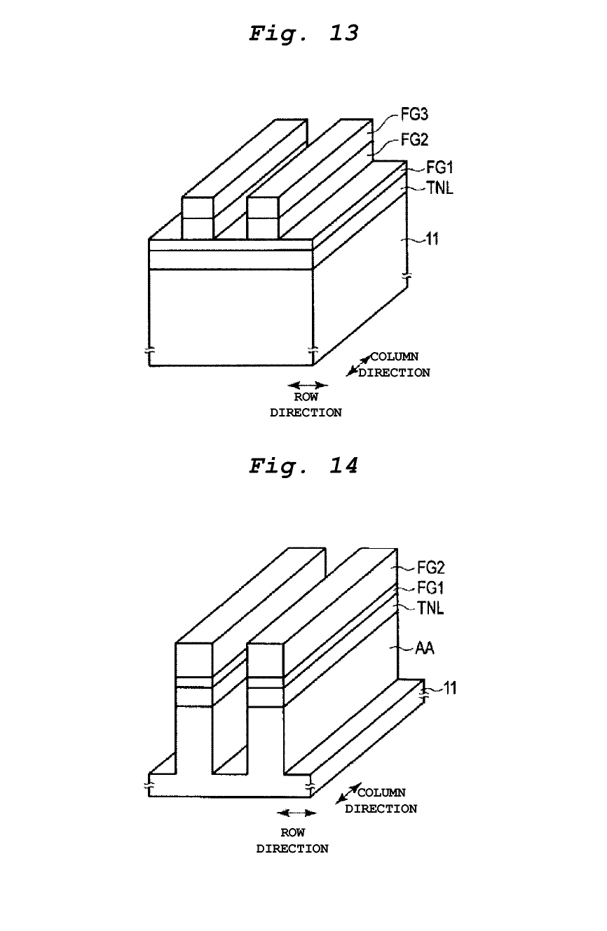

In this case, the metal layer (metal silicide layer) FG2 is formed by chemically reacting part of the semiconductor layer FG1 and part of the metal layer FG3 by heat, as shown in FIG. 13. The heat is generated during or after the process of FIG. 10 to FIG. 12, or by newly applying a thermal process.

Next, as shown in FIG. 14, using the metal layer FG2 as a mask, the semiconductor layer FG1, gate insulating film TNL, and semiconductor substrate 11 are sequentially etched by the RIE. As a result, the surface of the semiconductor substrate 11 is concave in parts and convex in other parts, and the fin-type active area AA is formed by the convex part.

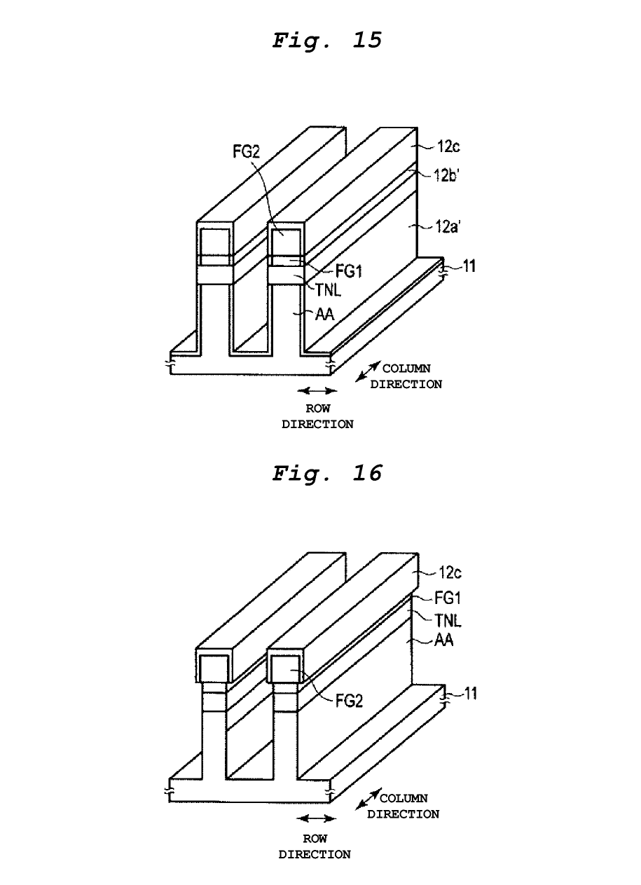

Next, as shown in FIG. 15, the surface of the semiconductor substrate 11 (including the fin-type active area AA), the surface of the semiconductor layer FG1, and the surface of the metal layer FG2 are simultaneously oxidized by RTO (rapid thermal oxidation).

As a result, an oxide layer 12a′ is formed on the surface of the semiconductor substrate 11, an oxide layer (first oxide layer) 12b′ is formed on the surface of the semiconductor layer FG1, and an oxide layer 12c is formed on the surface of the metal layer FG2.

Next, if the oxide layers 12a′ and 12b′ are selectively removed by wet-etching with dilute hydrofluoric acid (DHF), a structure shown in FIG. 16 can be obtained. As can be seen in FIG. 16, in addition to removing oxide layers 12a′ and 12b′, the wet-etching also removes an outer portion of the gate insulating film TNL.

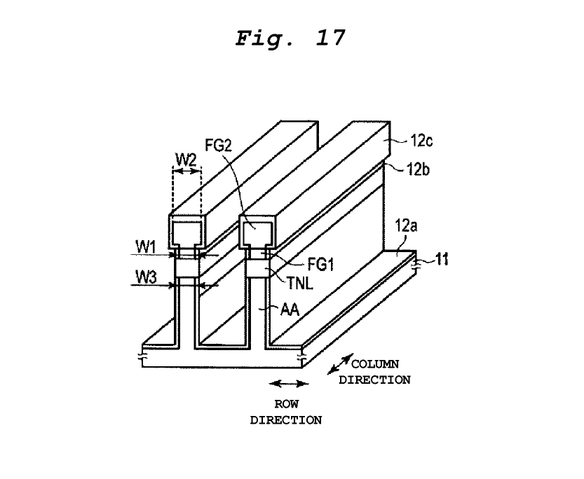

Next, as shown in FIG. 17, the surface of the semiconductor substrate 11 and the surface of the semiconductor layer FG1 are re-oxidized by the RTO. As a result, the oxide layer 12a is formed on the surface of the semiconductor substrate 11, and the oxide layer (second oxide layer) 12b is formed on the surface of the semiconductor layer FG1. As FIG. 17 illustrates, this re-oxidizing step also results in the formation of an oxidation layer on a bottom surface of metal layer FG2.

Therefore, the width W1 in the row direction of the semiconductor layer FG1 is narrower than the width W2 in the row direction of the metal layer FG2. In addition, the width W3 in the row direction of the fin-type active area AA is also narrower than the width W2 in the row direction of the metal layer FG2. The width of gate insulating film TNL may be less than W2. For example, it may be substantially the same as width W1 or width W3.

Here, the width W1 in the row direction of the semiconductor layer FG1 and the width W3 in the row direction of the fin-type active area AA can also be narrowed by the following process.

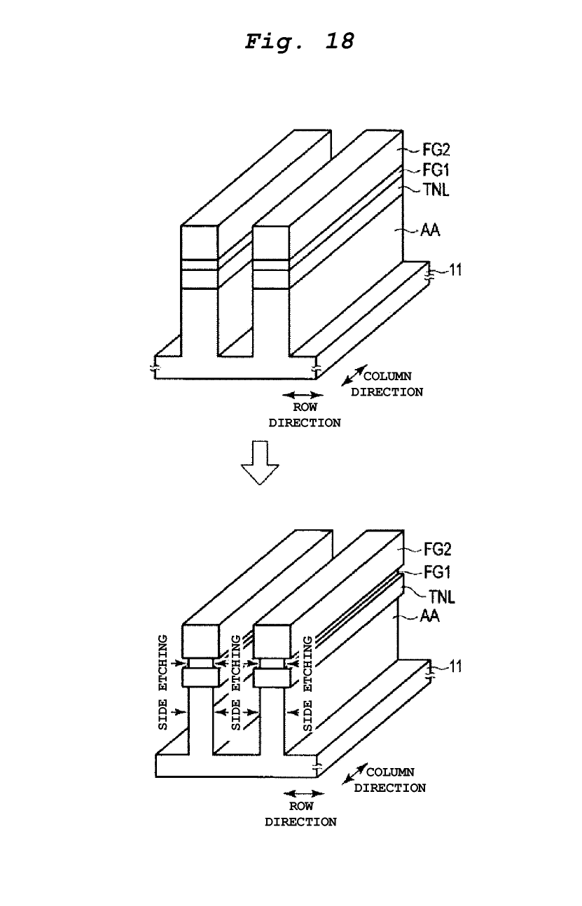

In other words, as shown in FIG. 18, after finishing the step shown in FIG. 14, the side surfaces of the semiconductor FG1 and the surface of the fin-type active area AA are selectively subjected to side etching by wet-etching.

Next, if the surfaces of the semiconductor substrate (including the fin-type active area AA) 11, the side surfaces of the semiconductor layer FG1, and the surfaces of the metal layer FG2 are simultaneously oxidized by the RTO, the same structure as the structure shown in FIG. 17 can be obtained.

FIG. 19 illustrates the next step in the fabrication process. This step follows the step depicted in FIG. 17. Next, as shown in FIG. 19, an insulating layer 25, which completely fills the spaces between adjacent fin-type active areas AA, is formed by a CVD (chemical vapor deposition) method. The insulating layer 25, for example, is a silicon nitride layer.

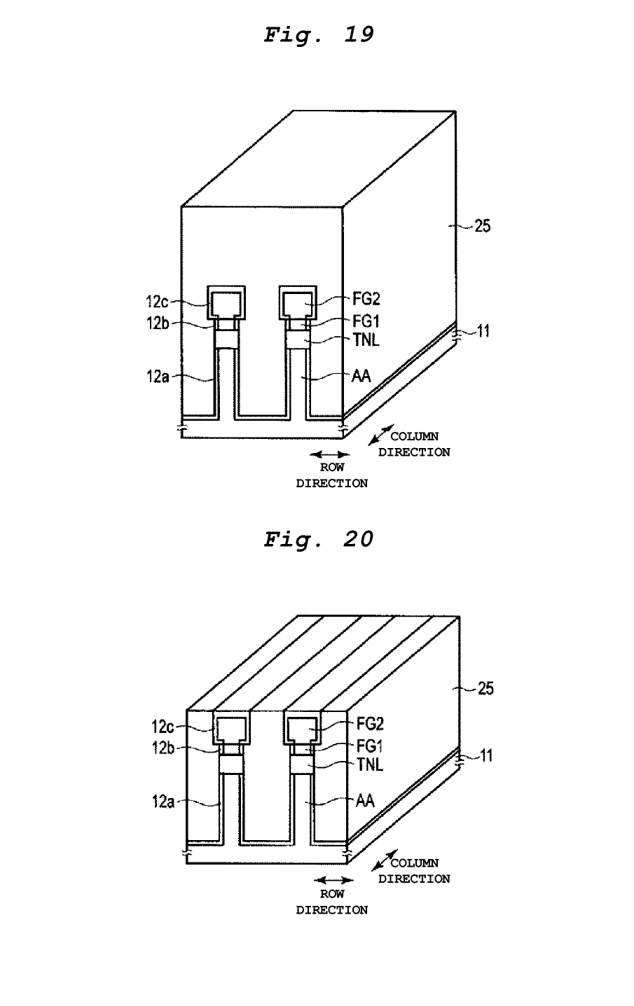

Next, as shown in FIG. 20, the insulating layer 25 is polished by the CMP until the upper surface of the insulating layer 12c on the metal layer FG2 is exposed.

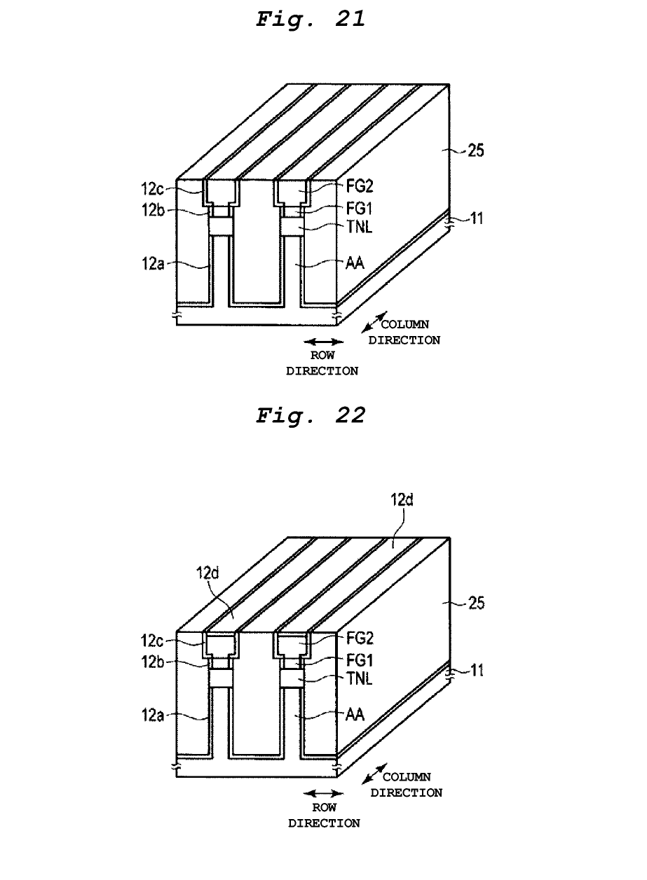

Here, as shown in FIG. 21, the insulating layer 12c on the top surface of metal layer FG2 may also be completely removed in the CMP. In this case, as shown in FIG. 22, since the oxide layer 12d, for example, is newly formed on the upper surface of the metal layer FG2 by natural oxidation, the structure of the second Embodiment can be finally obtained.

Here, the conditions of the CMP may be changed during the CMP. For example, the polishing of the insulating layer 25 can be a combination of a first condition in which the polishing speed of the insulating layer 25 is fast, and a second condition in which the polishing speed of the insulating layer 25 is slow.

In this case, with the implementation of the first condition and the second condition, the exposed timing of the upper surface of the insulating layer 12c can be precisely detected.

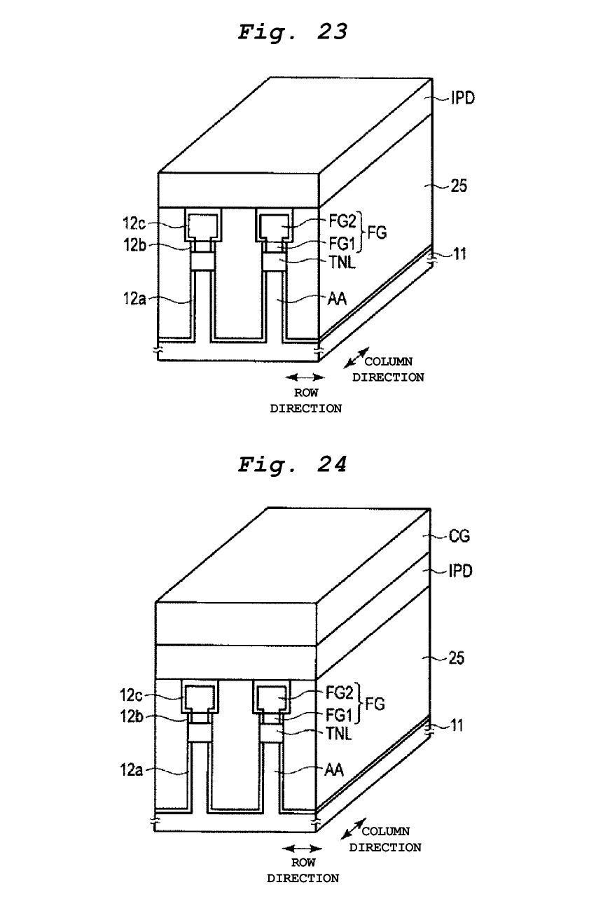

Next, as shown in FIG. 23, an insulating layer IPD between the electrodes is formed on the metal layer FG2 which constitutes the upper part of the floating gate electrode FG. At that time, since the substrate of the insulating layer IPD between the electrodes is flattened, a so-called flat cell structure can be realized. Next, as shown in FIG. 24, the control gate electrode CG is formed on the insulating layer IPD between the electrodes.

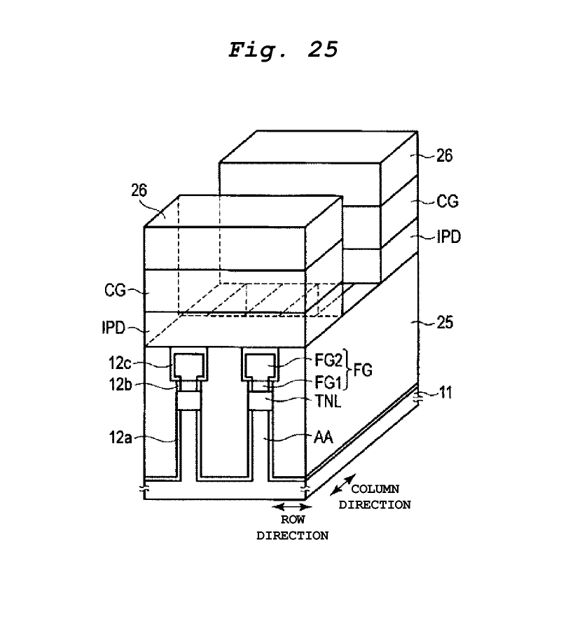

Next, as shown in FIG. 25, a photoresist layer 26 is formed on the control gate electrode CG by the PEP. The photoresist layer 26 has a line-and-space pattern that is arranged at a fixed pitch in the column direction and extends in the row direction.

Next, using the photoresist layer 26 as a mask, the control gate electrode CG and the insulating layer IPD between the electrodes are respectively patterned by the RIE. At that time, the floating gate electrodes (semiconductor layer FG1 and metal layer FG2) FG present in the area, which are not covered with the photoresist layer 26, are also etched.

In other words, the floating gate electrodes FG corresponding to a group of memory cells, which are connected in series in the column direction, are separated from each other.

Here, the mask layer 26, for example, is a hard mask layer for a sidewall patterning process (double patterning process). This process is known as a technique for realizing a narrow line width or narrow line pitch.

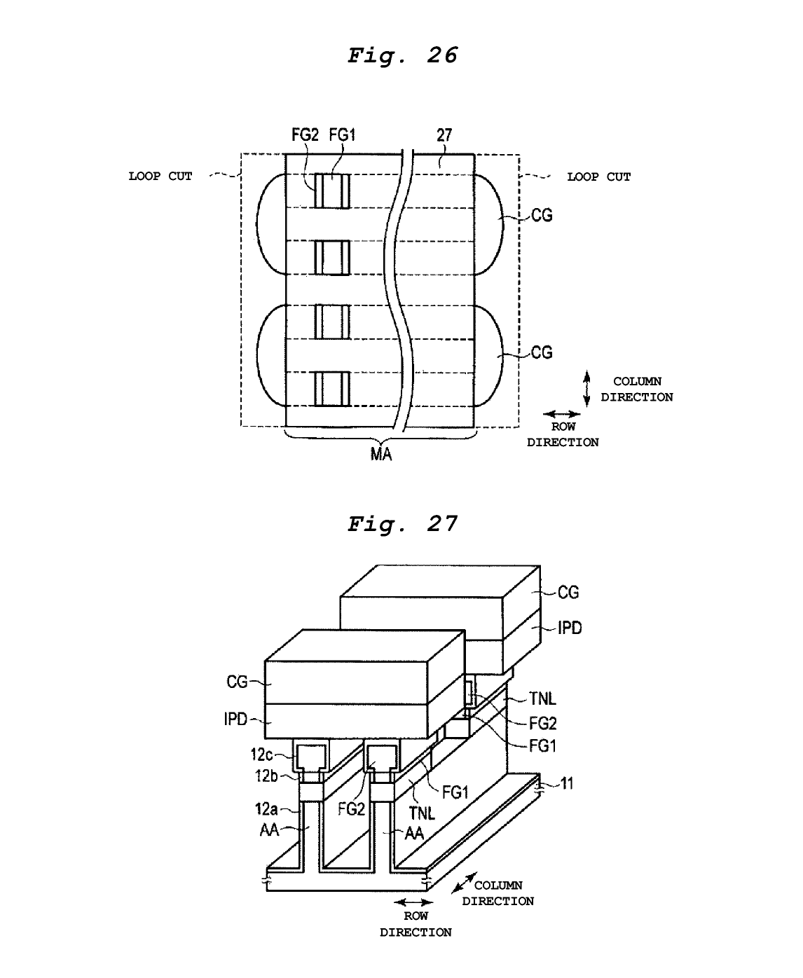

With the adoption of this process, as shown in FIG. 26, the control gate electrodes CG are patterned in a ring shape that extends in the row direction at the central part of the memory cell array and extends in the column direction at the ends.

Accordingly, the central part of the memory cell array MA is covered with a mask layer (for example, photoresist layer) 27, and using the mask layer 27 as a mask, the control gate electrode CG present at the end of the memory cell array MA is etched by the RIE (loop cut process).

Therefore, multiple control gate electrodes CG having a line-and-space pattern separated from each other are formed at the central part of the memory cell array MA.

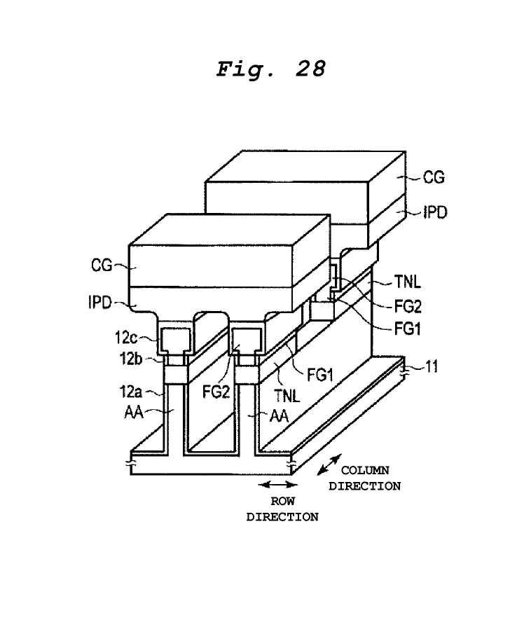

Finally, if the insulating layer 25 of FIG. 25 is removed by wet-etching with phosphoric acid, as shown in FIG. 27, air gaps AG are formed between the multiple fin-type active areas AA. Here, as shown in FIG. 28, part of the insulating layers IPD between the electrodes may also be etched in the wet-etching with phosphoric acid.

Through the above manufacturing method, the cell array structures of the first to third Embodiments are completed.

### Conclusion

According to these embodiments, the interference between the adjacent cells in the flat cell structure can be prevented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device, comprising:
a semiconductor substrate having a first active area protruding from a surface thereof;
a first insulating layer on the first active area;
a first floating gate electrode on the first gate insulating layer;
a second insulating layer on the first floating gate electrode and extending in a first direction; and
a first control gate electrode on the insulating layer which extends in the first direction, wherein
the first floating gate electrode includes a first semiconductor layer on the first gate insulating layer, and a first metal layer on the first semiconductor layer, and
a width of the first semiconductor layer in the first direction is narrower than a width of the first metal layer in the first direction.

2. The nonvolatile semiconductor storage device of claim 1, wherein a width of the active area in the first direction is narrower than a width of the first metal layer in the first direction.

3. The nonvolatile semiconductor storage device of claim 1, wherein
the first semiconductor layer is covered with an oxide layer that has a same element as the first semiconductor layer, and
the first metal layer is covered with an oxide that has a same element as the first metal layer.

4. The nonvolatile semiconductor storage device of claim 3, wherein the oxide layer covering the first semiconductor layer has a lower dielectric constant than a material of the second insulating layer.

5. The nonvolatile semiconductor storage device of claim 3, wherein a first surface of the first metal layer is covered with an oxide layer that is thicker than on other surfaces of the first metal layer, the other surfaces being adjacent to the first surface which abuts the second insulating layer.

6. The nonvolatile semiconductor storage device of claim 1, wherein the semiconductor layer is formed of polysilicon.

7. The nonvolatile semiconductor storage device of claim 1, wherein the first metal layer comprises two metal sub-layers, the two sub-layers being formed of different metals.

8. The nonvolatile semiconductor storage device of claim 7, wherein the two metal sub-layers are each covered with an oxide of the metal from which the sub-layer is formed.

9. The nonvolatile semiconductor storage device of claim 1, wherein the control gate electrode is made of one of polysilicon, metal silicide, and a laminate thereof.

10. The nonvolatile semiconductor storage device of claim 1, further comprising:
a second active area protruding from a surface thereof;
a third insulating layer on the second active area, and
a second floating gate electrode on the third insulating layer, wherein
the first and second active areas extend in the first direction,
the second insulating layer on the first floating gate electrode is arranged on the second floating gate electrode,
the second floating gate electrode comprises a second semiconductor layer on the third insulating layer, and a second metal layer on the second semiconductor layer, and
the width of the second semiconductor layer in the first direction is narrower than the width of the second metal layer in the first direction.

11. The nonvolatile semiconductor storage device of claim 10, wherein a gap is provided between the first and second floating gate electrodes.

12. The nonvolatile semiconductor storage device of claim 11, wherein a gap filled with silicon oxide is provided between the first and second floating gate electrodes.

13. The nonvolatile semiconductor storage device of claim 3, wherein a width of each of the first and second active areas in the first direction is less than a width of the first metal layer in the first direction.

14. The nonvolatile semiconductor storage device of claim 1, the first floating gate electrode further includes a second metal layer on the first metal layer.

15. A method for manufacturing a nonvolatile semiconductor storage device, the method comprising the steps of:
forming a gate insulating layer on a semiconductor substrate, a semiconductor layer on the gate insulating layer, and a mask on the semiconductor layer;
etching completely through the semiconductor layer and gate insulating layer using the mask and partially through the semiconductor substrate, to form a plurality of parallel trenches extending in a first direction;
initially oxidizing surfaces of the semiconductor substrate, semiconductor layer and first metal layer;
selectively etching the oxidized surfaces of the semiconductor substrate and the semiconductor layer; and
re-oxidizing the surfaces of the semiconductor substrate and the semiconductor layer to produce a plurality of stacked structures between the trenches, each stacked structure including an active area of the semiconductor substrate, the gate insulating layer, the semiconductor layer, and the metal layer, wherein the semiconductor layer has a width that is narrower than a width of the metal layer, the widths being measured along a second direction perpendicular to the first direction.

16. The method of claim 15, wherein a width of the active area in the second direction is narrower than a width of the metal layer in the second direction.

17. The method of claim 16, further comprising:
forming another metal layer on the metal layer.

18. A method for manufacturing a nonvolatile semiconductor storage device, the method comprising the steps of:
forming a gate insulating layer on a semiconductor substrate, a semiconductor layer on the gate insulating layer, and a mask on the semiconductor layer;
etching completely through the semiconductor layer and gate insulating layer using the mask and partially through the semiconductor substrate, to form a plurality of parallel trenches extending in a first direction;
selectively etching sidewalls of the trenches that are formed with the semiconductor substrate and the semiconductor layer; and
oxidizing surfaces of the semiconductor substrate, semiconductor layer and metal layer, to produce a plurality of stacked structures between the trenches, each stacked structure including an active area of the semiconductor substrate, the gate insulating layer, the semiconductor layer, and the metal layer, wherein the semiconductor layer has a width that is narrower than a width of the metal layer, the widths being measured along a second direction perpendicular to the first direction.

19. The method of claim 18, wherein a width of the active area in the second direction is narrower than a width of the metal layer in the second direction.

20. The method of claim 19, further comprising:
forming another metal layer on the metal layer.
